(19) United States
(12) Patent Application Publication
(10) Pub. No.: US 2021/0380875 A1
(43) Pub. Date: Dec. 9, 2021

(54) STABLE QUANTUM DOT FILM FOR DISPLAY APPLICATIONS

(71) Applicant: SABIC GLOBAL TECHNOLOGIES B.V., Beegen op Zoon (NL)

(72) Inventor: Bing ZHOU, Mount Vernon, IN (US)

(21) Appl. No.: 16/639,612

(22) PCT Filed: Aug. 17, 2018
(86) PCT No.: PCT/IB2018/056226

§ 371 Date: Feb. 17, 2020

Related U.S. Application Data
(60) Provisional application No. 62/546,683, filed on Aug. 17, 2017.

(51) Int. Cl. C09K 11/02; H01L 33/50

(52) U.S. Cl. CPC C09K 11/025; B82Y 20/00; H01L 33/504

(57) ABSTRACT

Provided are quantum dot film compositions, the compositions comprising a population of quantum dots bearing a passivation layer, the population of quantum dots being disposed in a matrix material. Also provided are methods of forming such compositions and devices that utilize such devices.

### TECHNICAL FIELD

The present disclosure relates to the field of quantum dot compositions and to the field of display technologies.

### BACKGROUND

Quantum dot (QD) are gaining more popularity in films incorporated into display technologies. Conventional semiconductor QDs, however, are sensitive to moisture and oxygen, and the QDs' performance can suffer with exposure to one or both of moisture and oxygen.

To protect QDs, existing approaches may dispose the QDs in a matrix material, following by disposing barrier films on the matrix material followed by disposing an additional layer or layers on the barrier films. Such structures, however, are comparatively thick, which in turn limits the structures' ability to be incorporated into thin and/or lightweight devices, such as mobile computing devices (e.g., smartphones, laptops). These structures are also comparatively expensive to fabricate, as the fabrication of the structures requires an environment that has little to no moisture and oxygen, and the fabrication of the structures also requires a number of time consuming and costly steps. In addition, the films require the use of a comparatively high number of QDs, which are themselves expensive. Further, existing QD films made according to currently-used methods do not always exhibit optimal resistance to moisture and oxygen, which in turn results in films that have shortened lifespans and may also exhibit suboptimal performance, resulting edge ingress and other issues. Accordingly, there is a long-felt need in the field for QD films having improved moisture and oxygen resistance, having a reduced number of QDs, having improved performance, and/or having improved lifetimes.

### SUMMARY

In meeting these long-felt needs in the art, the present disclosure teaches reducing the thickness and manufacturing cost of the QD film by using passivated nanoparticles. As one example, QDs (also termed nanoparticles, in some instances) are coated with a metal oxide of, for example, a minimum of 1 atom layer thickness, thereby providing localized protection at nanoscale. This can be achieved by surface modification or passivation. With controlled thickness and composition of the passivation layer, permeability to water and oxygen can be controlled with small impact on the optical properties.

The novel approach provided herein includes using quantum dots with their own intrinsic resistance to oxygen and water after surface modification and/or passivation. QDs can be purchased and used as purchased, or the surface of the QDs can be modified to have passivation layers (for example, metal oxide). Such an environmental barrier on the QDs helps to improve both thermal- and photo-stability while also retaining the desired optical properties of the QDs.

Better stability first allows for lower cost to manufacture nanocomposite without the need of maintaining inert environment around quantum dots throughout the process. Second, it also eliminates the need of barrier film in the structure of quantum dot film. The simplified design enhances the conversion efficiency, reduces the effect of edge ingress and is cost effective. More importantly, it opens up an opportunity to manufacture thin nanocomposite film with appropriate thickness for display application in smart phone, tablets and personal computers.

In meeting the described needs, the present disclosure first provides articles, comprising: a first matrix layer having dispersed therein a first plurality of quantum dots, the first plurality of quantum dots emit a first secondary light (for example, a first color) upon excitation by light produced from a light source; and the first plurality of quantum dots also having a first metal oxide coating disposed directly thereon; and a second matrix layer, the second matrix layer comprising a lower surface and an upper surface, the upper surface contacting the first matrix layer, the second matrix layer having dispersed therein a second plurality of quantum dots, the second plurality of quantum dots emit a second secondary light (for example, a second color) upon excitation by light produced from a light source; and the second plurality of quantum dots also having a second metal oxide coating disposed directly thereon.

The present disclosure also provides display devices, the devices comprising an article according to the present disclosure.

Further provided are methods, the methods comprising: in connection with forming at least a portion of a recorded or transmitted image, illuminating an article according to the present disclosure.

### BRIEF DESCRIPTION OF THE DRAWINGS

The following is a brief description of the drawings wherein like elements are numbered alike and which are exemplary of the various embodiments described herein. In the drawings:

FIG. 1 provides a cutaway view of a quantum dot (QD) film structure according to existing approaches (the QD surfaces are not passivated; green QDs are smaller circles within polymer nanocomposite and red QDs are larger circles in the polymer nanocomposite);

FIG. 2 provides a cutaway view of a QD film using passivated nanoparticles (passivation shown by dark black layer surrounding the QDs)—red QDs are comparatively larger than the green QDs; and

FIG. 3 provides a multi-layer structure of an exemplary QD film using passivated nanoparticles (passivation shown by the dark black layers surrounding the QDs)—green QDs are in the upper layer, and red QDs are in the lower layer.

### DETAILED DESCRIPTION OF ILLUSTRATIVE EMBODIMENTS

The present disclosure may be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used in the specification and in the claims, the term “comprising” may include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Numerical values in the specification and claims of this application, particularly as they relate to polymers or polymer compositions, oligomers or oligomer compositions, reflect average values for a composition that may contain individual polymers or oligomers of different characteristics. Furthermore, unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently combinable (for example, the range of “from 2 grams to 10 grams” is inclusive of the endpoints, 2 grams and 10 grams, and all the intermediate values). The endpoints of the ranges and any values disclosed herein are not limited to the precise range or value; they are sufficiently imprecise to include values approximating these ranges and/or values.

As used herein, approximating language may be applied to modify any quantitative representation that may vary without resulting in a change in the basic function to which it is related. Accordingly, a value modified by a term or terms, such as “about” and “substantially,” may not be limited to the precise value specified, in some cases. In at least some instances, the approximating language may correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” may refer to plus or minus 10% of the indicated number. For example, “about 10%” may indicate a range of 9% to 11%, and “about 1” may mean from 0.9-1.1. Other meanings of “about” may be apparent from the context, such as rounding off, so, for example “about 1” may also mean from 0.5 to 1.4. Further, the term “comprising” should be understood as having its open-ended meaning of “including,” but the term also includes the closed meaning of the term “consisting.” For example, a composition that comprises components A and B may be a composition that includes A, B, and other components, but may also be a composition made of A and B only. Any documents cited herein are incorporated by reference in their entireties for any and all purposes.

Owning to the high quantum yield and excellent wavelength tunability due to the nature of quantum confinement, cadmium and indium based nanoparticles have been studied intensively in academia and gradually found their ways in industrial applications, such as displays, photovoltaics and lightings. One popular material form for such applications is polymer nanocomposite film where nanoparticles are uniformly dispersed in matrix materials. In the industrial scale-up and production, a key challenge is to retain the original optical properties of cadmium and indium based semiconductor nanoparticles as they can quickly degrade and their optical performance is deteriorated upon exposure to oxygen or moisture in the ambient environment. Commercial production of quantum dot films is carefully operated under stringent inert environment throughout the process. Then the films are sandwiched in layers of barrier films with extremely low oxygen and moisture permeation to retain high quantum yield and conversion efficiency of nanoparticles. The high cost in manufacturing both nanocomposite and barrier film, in combination with the additional thickness of barrier film to the final assembly, limits the adoption of quantum dot film made thereby.

A barrier free and stable quantum dot film could expand the scope of its applications from traditional TV to increasingly more critical market segment of smart phone and table market.

Existing Approaches

In existing approaches to forming QD films, QDs (red and green QDs, typically) are embedded in a polymer matrix. The film is in turn illuminated by blue LEDs that are disposed behind the film, and the film may emit red or green light upon excitation; some blue light from LED source will also transmit through the composite.

In some existing approaches, nanoparticles (QDs) are synthesized and then transferred to a polymer matrix; this entails handling the QDs, mixing the QDs, transferring the QDs into the polymer matrix, and curing the polymers. These operations are conducted under stringent inert environment where oxygen and water are limited, as any contamination of quantum dots by water and oxygen in this process may lead to the loss of crucial optical properties, such as targeted quantum yield, peak wavelength, and full width at half maximum, and increase of the risk of generating off-spec composite film.

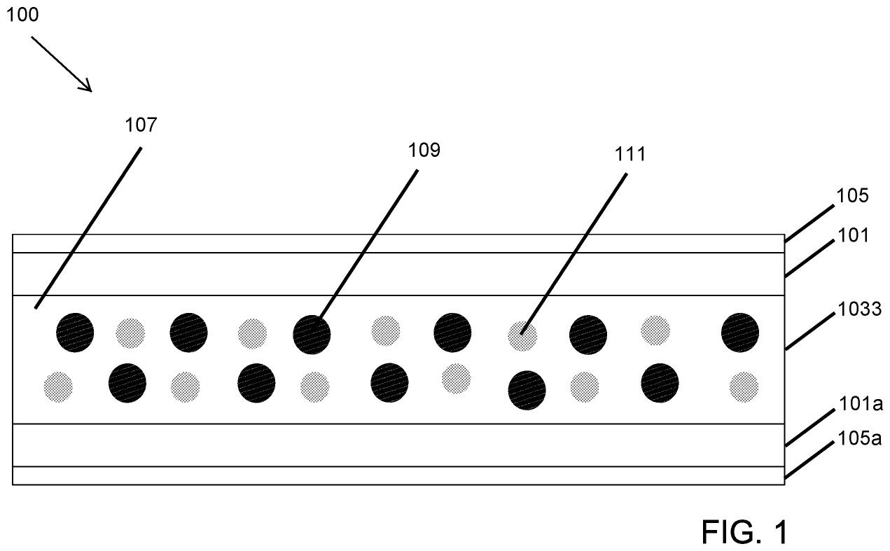

The polymer matrix of existing approaches serves to lock the QDs into place and to leave the QDs protected by matrix materials. The typical polymer materials used for these nanocomposites, however, do not have sufficiently low oxygen and water permeation to prevent premature degradation of nanoparticles before the designed lifetime of the film. As a consequence, a layer that is made from materials with lower permeability of oxygen and water is typically laminated onto each side of the nanocomposite. A typical design of the nanocomposite with barrier film is shown in FIG. 1.

As shown, in FIG. 1, both sides or surfaces of a traditional film 100 have barrier films 101, 101a for example, an polyester polymer (for example, polyethylene terephthalate, polybutylene terephthalate, etc.) surrounding a polymer nanocomposite layer 103. In turn, there is typically a coating layer 105, 105a such as a metal oxide on top of the barrier film layers 101, 101a. The overall production of such films can be expensive, and such films are also comparatively thick, with a total thickness of, for example, 200 micrometers (μm). Exemplary layer thicknesses are as follows: coating layer 10 nm, barrier film layer 50 μm, polymer nanocomposite

The middle layer is the polymer nanocomposite layer 103 where quantum dots are dispersed in a polymer matrix 107. The quantum dots 109, 111 in existing approaches, however, are not passivated. Further, nanocomposite films 103 protected by barrier films 101, 101a on their top and bottom sides (as shown in FIG. 1) are still prone to ingress of oxygen and moisture into the film through the unsealed sides of the films. Furthermore, the addition of the barrier layer may act to increase the inner reflection of lights at the interface of the different layers, in turn reducing the light absorption and luminance from the film. The loss of transmittance across the visible wavelength region through the barrier film may be high, for example, about 10%, which in turn negatively impacts the transparency of the nanocomposite film. In addition, the addition of the barrier films could double or even triple the original thickness of nanocomposite. As a consequence, the total thickness of such films is not suitable for application in many important markets, for example, smart phones, tablets, or even laptop, notebook, or desktop computers.

Disclosed Approach

Metal oxides are known to have low permeability of water and oxygen and are commonly used to coat the barrier film. In place of using separate barrier films that are in turn coated with additional layers of metal oxides, the present disclosure provides the approach of bringing the metal oxide onto the nanoparticles (QDs) and to completely encapsulate individual nanoparticle or nanoparticle cluster with at least 1 atom thick layer of metal oxide to provide localized protection at a nanometer scale, rendering the modified nanoparticles intrinsically more robust.

The foregoing may be achieved by surface modification or passivation. By tailoring the composition and thickness of the metal oxide passivation layer, the permeability of water and oxygen can be controlled while has relatively small impact on the optical properties of the passivated nanoparticles.

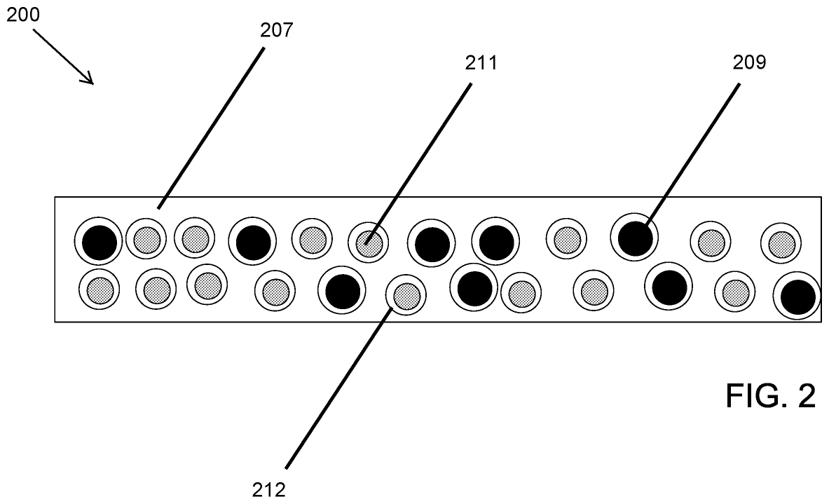

One example of this is shown in FIG. 2 of a nanocomposite 200 and shows red QDs 209 and green QDs 211 (the respective colors red and green are according to their emission wavelengths) disposed within the same polymer matrix material layer. The nanoparticles/quantum dots 209, 211 (QDs) are shown encapsulated with at least 1 atom thick layer of metal oxide 212. Because the emitted light from green nanoparticles 211 may be reabsorbed by red nanoparticles 209 or Forster resonance energy transfer (FRET) could also occur if red nanoparticles 209 and green nanoparticles are in close proximity, for example a few nanometer apart from each other, the number of green nanoparticles is higher than, for example, seven to ten times higher the number of red nanoparticles in order to adjust the red shift of emission peaks and match the desired white points for the display. This reabsorption or FRET reduces the conversion efficiency, and the necessarily higher loading of green nanoparticles increases the production cost, as the ratio of green QDs to red QDs may be comparatively high.

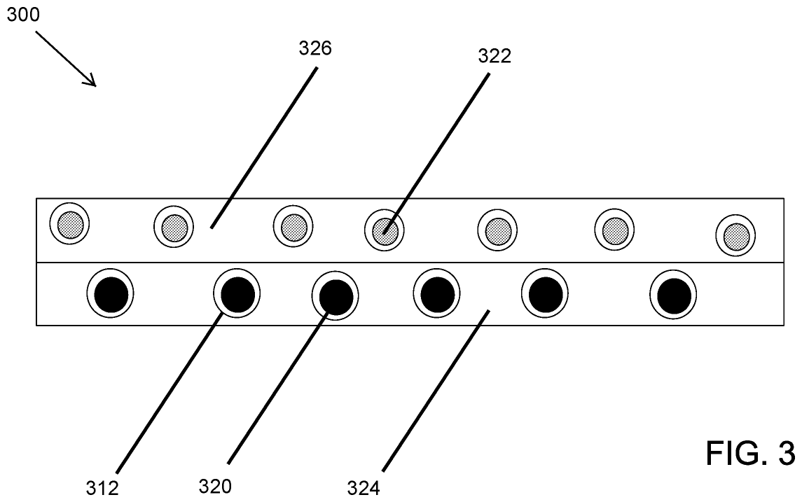

A preferred nanocomposite 300 design according to the present disclosure is shown in FIG. 3. In this embodiment, red nanoparticles 320 and green nanoparticles 322 are embedded in different or distinct polymer matrix layers 324, 326. The nanoparticles/quantum dots 320, 322 (QDs) are shown encapsulated with at least 1 atom thick layer of metal oxide 312. By selectively orienting a first polymer matrix layer 324 having the red QDs 320 closer to a blue LED light source (not shown) and by placing the green QDs 322 in a second polymer matrix layer 326 layer farther from the blue LED light source, the reabsorption and FRET issues presented by the design of FIG. 2 are minimized; while the red QDs 320 will absorb the blue LED light and emit red light, the red emission will not be absorbed by the green QDs 322. In the meantime, because the red QDs 320 and green QDs 322 are well separated spatially by the layered structure, the necessary requirement for the FRET to occur is not met. As a result, the total amount of nanoparticles used may be reduced.

Thus, the inventive approach shown in FIG. 3 provides a number of advantages over the existing conventional approaches. Some advantages of the inventive approach include:

Comparatively low infrastructure investment for manufacturing QD film. The localized protection provided by the on-QD passivation layers help to isolate the quantum dot core from contact with outer environments during manufacturing process, thus retaining the optical properties and extending the shelf life. With intrinsically protected QDs, the manufacturing process of the compositions is greatly simplified, as there is no longer a need to maintain an inert environment. This in turn saves significant infrastructure, thus improving production yield and also providing a process that can be scaled up easily.

Thinner Displays. In the manufacturing process of metal oxide (such as, for example, aluminum oxide Al₂O₃, titanium oxide TiO₂, etc.) coated barrier films, the clusters of Al₂O₃ are deposited on the surface of barrier film. To ensure the clusters of Al₂O₃ are connected to the neighboring cluster to form a seamless layer of film without local defects (uncovered area by Al₂O₃), a minimum of tens of nanometers thickness of coating layer (typically varying from 10 to 40 nm) may be used to minimize the number of defects. The longer deposition time, however, can drastically increase the production cost, making the barrier film layer an expensive component. At this thickness, the expected lifetime of nanoparticle is approximately 20,000 to 30,000, even greater than 70,000 hours (24 years based on a daily use of 8 hours), which is a significant overdesign for smartphone and tablet application.

In the present disclosure, the passivation layer (for example Al₂O₃) is applied at, for example, a few-nanometer thickness onto the QDs, as the thickness of passivation required to cover quantum dots is small as compared to the barrier film design. Hence, only a few nanometers of passivation disposed on individual QDs can deliver equivalent or better performance in terms of oxygen permeability to the cores of encapsulated QDs. As one non-limiting example, the passivation layer thickness in QDs according to the present disclosure may be significantly lower than the thickness of 3M Ultrabarrier™ films (around tens of nanometers) that are used in the field, and is also lower than the 100 nanometer (nm) or tens-of-microns thickness of other thin film encapsulation suppliers. This in turn renders the disclosed films suitable for flexible and even foldable electronic displays.

Furthermore, the thinness of the disclosed films meets the thickness requirements applicable to mobile phones, tablets, and computers; at present, there is no QD display having the necessary thinness, and the disclosed films have a thickness of only 30% to 50% the thickness of commercial quantum dot films, thereby enabling their use in key technology markets. The overall weight of barrier free film construction also is reduced by approximately 30% to 60% accompanying the thickness reduction from the elimination of barrier film and metal oxide layers, which further differentiates the disclosed technology from other alternatives and provides another competitive advantage in this market segment.

Reduction of Light Absorption. The barrier films of the existing approaches reduce the light absorption received by nanoparticles and the following emission, and in turn lead to reduced light conversion efficiency. By contrast, the disclosed nanocomposite does not suffer from the efficiency shortcomings of the existing approaches.

Element A: QD film for display

Element B: nanoparticle composite

Element C: metal oxide passivation layer on nanoparticles

Element D: Intrinsic resistance to moisture and oxygen ingress

Element E: reduced thickness and lower weight

Element F: Barrier film free optical construction

### Exemplary Embodiments

The following embodiments are illustrative only and do not limit the scope of the present disclosure.

Embodiment 1A. An article, comprising: a first matrix layer having dispersed therein a first plurality of quantum dots, the first plurality of quantum dots emit a first secondary light (for example, first color) upon excitation by light produced from a light source; and the first plurality of quantum dots also having a first metal oxide coating disposed directly thereon; and a second matrix layer, the second matrix layer comprising a lower surface and an upper surface, the upper surface contacting the first matrix layer, the second matrix layer having dispersed therein a second plurality of quantum dots, the second plurality of quantum dots emit a second secondary light (for example, second color) upon excitation by light produced from a light source; and the second plurality of quantum dots also having a second metal oxide coating disposed directly thereon.

Embodiment 1B. An article, consisting essentially of: a first matrix layer having dispersed therein a first plurality of quantum dots, the first plurality of quantum dots emit a first secondary light (for example, first color) upon excitation by light produced from a light source; and the first plurality of quantum dots also having a first metal oxide coating disposed directly thereon; and a second matrix layer, the second matrix layer comprising a lower surface and an upper surface, the upper surface contacting the first matrix layer, the second matrix layer having dispersed therein a second plurality of quantum dots, the second plurality of quantum dots emit a second secondary light (for example, second color) upon excitation by light produced from a light source; and the second plurality of quantum dots also having a second metal oxide coating disposed directly thereon.

Embodiment 1C. An article, consisting of: a first matrix layer having dispersed therein a first plurality of quantum dots, the first plurality of quantum dots emit a first secondary light (for example, first color) upon excitation by light produced from a light source; and the first plurality of quantum dots also having a first metal oxide coating disposed directly thereon; and a second matrix layer, the second matrix layer comprising a lower surface and an upper surface, the upper surface contacting the first matrix layer, the second matrix layer having dispersed therein a second plurality of quantum dots, the second plurality of quantum dots emit a second secondary light (for example, second color) upon excitation by light produced from a light source; and the second plurality of quantum dots also having a second metal oxide coating disposed directly thereon.

Embodiment 2. The article of any of embodiments 1A-1C, further comprising a light-emitting diode configured to illuminate the lower surface of the second matrix layer.

Embodiment 3. The article of any of embodiments 1A-2, wherein the first emitted color is green. A green QD may be a QD having a cross-sectional dimension of from about 1 nanometers (nm) to about 500 nm. Upon excitation by light source, a green QD may emit a secondary light with a majority of emitted light in the wavelength range between about 490 nm to about 580 nm.

Green QDs may comprise an element from any of Groups II-VI, IV-VI, or a III-V semiconductor material, for example, cadmium sulfide CdS, cadmium selenide CdSe, cadmium telluride CdTe, zinc sulfide ZnS, zinc selenide ZnSe, zinc telluride ZnTe, zinc oxide ZnO, mercury sulfide HgS, mercury selenide HgSe, mercury telluride HgTe, gallium nitride GaN, gallium phosphide GaP, gallium arsenide GaAs, gallium antimonide GaSb, aluminum nitride AlN, aluminum phosphide AlP, aluminum arsenide AlAs, aluminum antimonide AlSb, indium nitride InN, indium phosphide InP, indium arsenide InAs, indium antimonide InSb, tin sulfide SnS, tin selenide SnSe, tin telluride SnTe, lead sulfide PbS, lead selenide PbSe, lead telluride PbTe, silicon carbide SiC, silicon SiGe, gallium arsenide GaAs, gallium phosphide GaP, gallium antimonide GaSb, mercury sulfide HgS, mercury selenide HgSe, mercury telluride HgTe, indium arsenide InAs, indium phosphide InP, and indium antimonide InSb alloys thereof, gradient thereof and mixtures thereof.

A QD may comprise a semiconductor shell that has a different composition with quantum dots. Examples of semiconductor shells include, but are not limited to CdS, ZnS, lead sulfide PbS, CdSe, ZnSe, lead selenide PbSe, ZnTe, lead telluride PbTe, CdTe, cadmium zinc sulfide CdZnS, cadmium zinc selenide CdZnSe, cadmium zinc telluride CdZnTe, cadmium zinc telluride selenide CdZnTeSe, cadmium zinc sulfide selenide CdZnSSe, GaAs, GaP, GaN, InP, InAs, gallium aluminum arsenide GaAlAs, gallium aluminum phosphide GaAlP, gallium aluminum nitride GaAlN, gallium indium nitride GaInN, gallium aluminum arsenide phosphide GaAlAsP, or gallium aluminum indium nitride GaAlInN.

Embodiment 4. The article of any of embodiments 1A-3, wherein the second emitted color is red. “Red” QDs may comprise QDs having a size from about 1 nanometers (nm) to about 500 nm. Upon excitation by light source, a red QD may emit a secondary light with a majority of emitted light in the wavelength range between about 600 nm to about 750 nm.

The plurality of “red” quantum dots comprise an element from any of Groups II-VI, IV-VI, or a III-V semiconductor material, for example, CdS, CdSe, CdTe, ZnS, ZnSe, ZnTe, ZnO, HgS, HgSe, HgTe, GaN, GaP, GaAs, GaSb, AlN, AlP, AlAs, AlSb, InN, InP, InAs, InSb, SnS, SnSe, SnTe, PbS, PbSe, PbTe, SiC, SiGe, GaAs, GaP, GaAs, GaSb, HgS, HgSe, HgTe, InAs, InP, InSb, AlAs, alloys thereof, gradient thereof and mixtures thereof. A QD may comprise a semiconductor shell that has a different composition with quantum dots. Examples of semiconductor shells include, but are not limited to CdS, ZnS, PbS, CdSe, ZnSe, PbSe, ZnTe, PbTe, CdTe, CdZnS, CdZnSe, CdZnTe, CdZnTeSe, CdZnSSe, GaAs, GaP, GaN, InP, InAs, GaAlAs, GaAlP, GaAlN, GaInN, GaAlAsP, or GaAlInN.

Embodiment 5. The article of any of embodiments 1A-4, wherein the first emitted color of quantum dots is green, wherein the second emitted color of quantum dots is red, and wherein the number ratio of green to red quantum dots is less than about 7:1.

Embodiment 6. The article of embodiment 5, wherein the number ratio of green to red quantum dots is less than about 5:1.

Embodiment 7. The article of embodiment 6, wherein the number ratio of green to red quantum dots is less than about 2:1.

Embodiment 8. The article of any of embodiments 1A-7, wherein the first layer defines a thickness in the range of from about 10 nm to about 10 mm. For example, the first layer may define a thickness in the range of from about 10 nm to about 10 mm, from about 20 nm to about 5 mm, from about 50 nm to about 1 mm, from about 100 nm to about 0.5 mm, from about 500 nm to about 0.1 mm, from about 1000 nm to about 100,000 nm, from about 10,000 nm to about 50,000 nm. Thicknesses in the range of from about 10 nm to about 1000 nm, from about 10 nm to about 500 nm, from about 10 nm to about 200 nm, or even from about 10 nm to about 100 nm are all considered especially suitable.

Embodiment 9. The article of any of embodiments 1A-8, wherein the second layer defines a thickness in the range of from about 10 nm to about 10 mm. For example, the second layer may define a thickness in the range of from about 10 nm to about 10 mm, from about 20 nm to about 5 mm, from about 50 nm to about 1 mm, from about 100 nm to about 0.5 mm, from about 500 nm to about 0.1 mm, from about 1000 nm to about 100,000 nm, from about 10,000 nm to about 50,000 nm. Thicknesses in the range of from about 10 nm to about 1000 nm, from about 10 nm to about 500 nm, from about 10 nm to about 200 nm, or even from about 10 nm to about 100 nm are all considered especially suitable.

Embodiment 10. The article of any of embodiments 1A-9, wherein the first and second layers define a combined thickness in the range of from about 20 nm to about 20 mm. For example, the combined thickness may be in the range of from about 20 nm to about 10 mm, from about 20 nm to about 5 mm, from about 20 nm to about 1 mm, from about 20 nm to about 0.1 mm, from about 20 nm to about 10,000 nm, from about 20 nm to about 1000 nm, or even from about 20 nm to about 500 nm.

Embodiment 11. The article of any of embodiments 1A-10, wherein the first metal oxide coating, the second metal oxide coating, or both comprise one or more of, for example, alumina (AlOx), magnesium oxide (MgOx), zirconium oxide (ZrOx), titanium oxide (TiOx), silicon oxide (SiOx), chromium oxide (CrOx), copper oxide (CuOx), cobalt oxide (CoO), iron oxide (FeOx), and vanadium oxide (VOx) or alloy thereof or a mixture thereof. A metal oxide coating may define a thickness in the range of from about 0.1 to about 500 nm, from about 1 to about 100 nm, or even from about 5 to about 50 nm. Coating thicknesses in the range of from about 1 to about 100 nm are considered especially suitable.

The combination of QD and coating will depend on the user's needs. As one example, one might coat a CdSe alloy-gradient QD having a semiconductor ZnS shell with a coating of Al₂O₃.

Embodiment 12. The article of any of embodiments 1A-11, wherein the first matrix layer is exposed to the environment exterior to the first matrix layer. In some embodiments, this means that there is no barrier layer needed, unlike existing approaches. Hence, layers in films made according to the present disclosure may thus adhere to other functional films, for example, diffuser films, brightness enhancement films, and the like, via an optically clear adhesive (OCA), as part of production. This approach is not compatible with existing barrier-layer-type approaches, as despite the presence of the barrier layer, the sides of the QD-containing layers are nonetheless exposed to the exterior environment. The OCA and the additional films don't provide sufficient barrier function to prevent the migration of moisture and oxygen, and the QDs of the existing approaches—which QDs are not passivated by metal oxides or any other material—are prone to degradation.

Embodiment 13. The article of any of embodiments 1A-12, wherein the article exhibits a reduced permeation of water across the first matrix layer and second matrix layer such that the article maintains at least 90% of its quantum yield performance after 500 hours of exposure according to ASTM F1249-13.

For a QD film without barrier layers, a typical range for the water vapor transmission rate WVTR is from 1 gram per square meter per day (g/m²/day) to 200 g/m²/day at the thickness of 100 μm, dependent on the type of polymer and testing conditions (temperature and relative humidity). As one example, for a poly methyl methacrylate QD film with a thickness of around 100 μm, the WVTR is around 40 g/m²/day when tested at 50° C. and 100% RH

Embodiment 14. The article of any of embodiments 1A-13, wherein the article exhibits quantum yield of from about 50% to 95% before photo-thermal aging to about 45% to 90% after the photo-thermal aging, when measured according to international standard International Electrotechnical Commission IEC 62607-3-1; light illumination at 6,561.68 candela per meter (cd/m) (2000 lumens per square foot (lumens/ft)) with a test temperature of 50° C. Thus, the decrease in quantum yield may be from about 5 to about 50%, or from about 5 to about 45%, or from about 5 to about 40%, or from about 5 to about 35%, or from about 5 to about 30%, or from about 5 to about 25%, or from about 5 to about 20%, or from about 5 to about 15%, or from about 5 to about 10%, or even about 5%.

The initial quantum yield of quantum dots measured in solution phase may be around 50% to 95%, depending on the type of quantum dots, their size, and the surrounding environment, similar to that of non-passivated quantum dots. When the films prepared from passivated quantum dots or non-passivated quantum dots are exposed to high flux of photons and the elevated temperature (50° C.) found in the accelerated photo thermal degradation, the quantum yield of non-passivated QDs in films prepared in the same fashion reaches to 10% or less after an exposure time of less than 30 minutes. Under these same conditions, however, the quantum yield of passivated quantum dots drops only slightly (by a few percent), and the passivated QDs are stable over time with a final quantum yield of 45% to 90% after 20 days of exposure time. Quantum yield may be suitably measured in solution phase at room temperature after quantum dots are dissolved in toluene; the excitation light wavelength is set to 450 nm, the wavelength of blue LED light source. The quantum yield may be measured by, for example, a Horiba spectrofluorometer Fluoromax-4 series with 15 cm Quanta-Φ integration sphere or other such instrument.

Embodiment 15. The article of any of embodiments 1A-14, wherein the article exhibits a change in initial or extended color shift using CIE 1976 uniform chromaticity scale (u′v′) of from about 0 to about 0.02 following UV light illumination at 6,561.68 cd/m (2000 lumens/ft) and a test temperature of 50° C. for a duration of 500 hours. The color shift is calculated using the following equation:

Δu′v′=+\sqrt{(u′ₜ−u′ᵣ)²+(v′ₜ−v′ᵣ)²}

where r is collected at time zero and t is the collected at the specific elapsed time.

The change in yellowness index typically reflects the stability (photo or thermal) of the polymeric matrix after aging tests. Stability of quantum dots may be monitored by examining the emission profile of the secondary light of quantum dots after the excitation by light from the source. Band profile, peak wavelength, emission intensity and quantum yield are measured according to the IEC 62607-3-1. The color coordinate may be calculated based on two standards, set by international commission on Illumination, CIE 1931 and CIE 1976.

Embodiment 16. The article of any of embodiments 1A-15, wherein the article exhibits a quantum yield in the range of about 50% to about 95%.

As explained elsewhere herein, compared to existing technology, the disclosed technology brings an intrinsic resistance of moisture and oxygen to the level of individual QDs.

If the same barrier film free design is used for both conventional quantum dots and quantum dots with metal oxide passivation layer, the performance is different. When the films made thereby go through accelerated photo-thermal degradation (high intensity UV light and at elevated temperature (50° C.)), a film according to the present disclosure and made from passivated QDs can have a relatively constant quantum yield and conversion efficiency for hundreds of hours, while the film from conventional quantum dots may only sustain its performance for several hours before the permanent loss of fluorescing capability.

As described elsewhere herein, the barrier-free design in this disclosure has application in the small screens for smart phones or tablets. For traditional TV applications, the reduced thickness of QD films also brings more freedom to the design space for backlight units. For example, as in the edge-lit designs found in many current liquid crystal displays/light emitting diode LCD/LED TVs, the blue LED light sources are placed around the edge of TV to reduce the total thickness of backlighting unit. With reduced thickness disclosed here, the flexibility of design can be improved.

Embodiment 17. A display device comprising an article according to any of embodiments 1A-16.

Embodiment 18. The display device of embodiment 17, wherein the display device is comprised in a mobile computing device.

Embodiment 19. The display device of embodiment 18, wherein the mobile computing device is configured to communicate with a cellular communications network.

Embodiment 20. A method, comprising: in connection with forming at least a portion of a recorded or transmitted image, illuminating an article according to any of embodiments 1A-16. The illumination may be effected by a light-emitting diode (LED); blue LEDs are considered especially suitable.

While typical aspects have been set forth for the purpose of illustration, the foregoing descriptions should not be deemed to be a limitation on the scope herein. Accordingly, various modifications, adaptations, and alternatives can occur to one skilled in the art without departing from the spirit and scope herein.

It will be apparent to those skilled in the art that various modifications and variations can be made in the present disclosure without departing from the scope or spirit of the disclosure. Other embodiments of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

The patentable scope of the disclosure is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An article comprising:
a first matrix layer having dispersed therein a first plurality of quantum dots,
the first plurality of quantum dots emit a first secondary light upon excitation by light produced from a light source; and the first plurality of quantum dots also having a first metal oxide coating disposed directly thereon; and
a second matrix layer,
the second matrix layer comprising a lower surface and an upper surface, the upper surface contacting the first matrix layer,
the second matrix layer having dispersed therein a second plurality of quantum dots,
the second plurality of quantum dots emit a second secondary light upon excitation by light produced from a light source and the second plurality of quantum dots also having a second metal oxide coating disposed directly thereon.

2. The article of claim 1, further comprising a light-emitting diode configured to illuminate the lower surface of the second matrix layer.

3. The article of claim 1, wherein the first emitted light upon excitation corresponds to a wavelength of a green color.

4. The article of claim 1, wherein the second emitted light upon excitation corresponds to a wavelength of a red color.

5. The article of claim 1, wherein a first color of quantum dots is green, wherein a second color of quantum dots is red, and wherein a number ratio of green quantum dots to red quantum dots is less than about 7:1.

6. The article of claim 5, wherein the number ratio of green quantum dots to red quantum dots is less than about 5:1.

7. The article of claim 6, wherein the number ratio of green quantum dots to red quantum dots is less than about 2:1.

8. The article of claim 1, wherein the first matrix layer defines a thickness in the range of from about 10 nm to about 10 mm.

9. The article of claim 1, wherein the second matrix layer defines a thickness in the range of from about 10 nm to about 10 mm.

10. The article of claim 1, wherein the first and second layers define a combined thickness in the range of from about 20 nm to about 20 mm.

11. The article of claim 1, wherein the first metal oxide coating, the second metal oxide coating, or both comprise one or more of alumina (AlOx), magnesium oxide (MgOx), zirconium oxide (ZrOx), titanium oxide (TiOx), silicon oxide (SiOx), chromium oxide (CrOx), copper oxide (CuOx), cobalt oxide (CoO), iron oxide (FeOx), and vanadium oxide (VOx) or a combination of them.

12. The article of claim 1, wherein the first matrix layer is exposed to an environment exterior to the first matrix layer.

13. The article of claim 1, wherein the article exhibits a reduced permeation of water and oxygen across the first matrix layer and second matrix layer to cores of quantum dots such that the article maintains at least 90% of its original quantum yield performance after 500 hours of exposure according to IEC 62607-3-1.

14. The article of claim 1, wherein the article exhibits a quantum yield of from about 50% to 95% before accelerated photo-thermal aging to about 45% to 90% after aging, when measured according to international standard IEC 62607-3-1 following light illumination at 6,561.68 cd/m (2000 lumens/ft) with a test temperature of 50° C.

15. The article of claim 1, wherein the article exhibits a color change in CIE 1976 uniform chromaticity scale (Δu′v′) from about 0 to about 0.02 following UV light illumination at 6,561.68 cd/m (2000 lumens/ft) and a test temperature of 50° C. for a duration of 500 hours.

16. The article of claim 1, wherein the article exhibits a quantum yield in the range of about 50% to about 95%.

17. A display device comprising an article according to claim 1.

18. The display device of claim 17, wherein the display device is comprised in a mobile computing device.

19. The display device of claim 18, wherein the mobile computing device is configured to communicate with a cellular communications network.

20. A method, comprising: in connection with forming at least a portion of a recorded or transmitted image, illuminating an article according to claim 1.
